(19) United States
(12) Patent Application Publication
(10) Pub. No.: US 2025/0127064 A1
(43) Pub. Date: Apr. 17, 2025

(54) DEVICE FOR PREVENTING CONTAMINATION OF CHAMBER WINDOW IN PULSED LASER DEPOSITION

(71) Applicant: MARU L&C Co., Ltd., Daegu (KR)

(72) Inventor: Dong Jin KIM, Daegu (KR)

(21) Appl. No.: 18/937,123

(22) Filed: Nov. 5, 2024

Related U.S. Application Data
(63) Continuation of application No. PCT/KR2024/095883, filed on Jun. 13, 2024.

(30) Foreign Application Priority Data
Oct. 11, 2023 (KR) 10-2023-0134750

(51) Int. Cl. H10N 60/01; C23C 14/34

(52) U.S. Cl. CPC H10N 60/01; C23C 14/3485

(57) ABSTRACT

Embodiments of the present invention relate to a device for preventing contamination of a chamber window, which enables a PLD process to be performed for a long period of time without replacing the chamber window, by improving an existing technology, in which a deposition material is deposited on the chamber window, and thus, a process has to be stopped, and the maintenance has to be performed, in a pulsed laser deposition (PLD), which irradiates a thin film with pulsed laser to deposit the generated plume on a substrate.

### CROSS-REFERENCE TO RELATED APPLICATION

This application is a continuation application of International Patent Application No. PCT/KR2024/095883, filed on Jun. 13, 2024, which claims priority to Korean Patent Application No. 10-2023-0134750 filed on Oct. 11, 2023 and all the benefits accruing therefrom under 35U.S.C. § 119, the contents of which are incorporated by reference in their entirety.

### BACKGROUND

The following embodiments relate to a device for preventing contamination of a chamber window, which enables a PLD process to be performed for a long period of time without replacing the chamber window, by improving an existing technology, in which a deposition material is deposited on the chamber window, and thus, a process has to be stopped, and the maintenance has to be performed, in a pulsed laser deposition (PLD), which irradiates a thin film with pulsed laser to deposit the generated plume on a substrate.

Recently, due to miniaturization and high integration of electronic and electrical devices, elements used in each device are also becoming miniaturized and highly integrated. To achieve the miniaturization and high integration of the elements, oxide thin film elements such as superconductors and semiconductors are widely used, and it is most important to form the thin films thinly, widely, and evenly.

Sputtering deposition or pulsed laser deposition is widely used to form the superconductors, the semiconductor, or the oxide thin films. The element is completed by depositing a superconducting thin film on an upper portion of the substrate or depositing an electrode on the upper portion of the substrate to deposit a dielectric thin film on an upper portion of the electrode so as to deposit the electrode on an upper portion of the dielectric thin film.

In general, a pulsed laser deposition apparatus is an apparatus that deposits a thin film on a substrate by positioning a target (thin film) at a position facing the substrate in a vacuum chamber and then focusing and irradiating pulsed laser beam, which is adjusted in focal length and an angle by a lens or mirror formed outside the chamber, onto the target.

Here, a high-temperature target on which the pulsed laser beam is focused generates an atomic gas, and the atomic gas reaches the substrate as a plume, thereby causing deposition through a chemical reaction on the substrate surface.

However, as the conventional pulsed laser deposition apparatus performs a process for a long time, an evaporated and scattered deposition material is deposited on the chamber window made of a transparent material placed at a portion, at which the laser is introduced into the vacuum chamber, to reduce energy of the pulsed laser beam, thereby reducing an amount of deposition and deteriorating uniformity of the thin film.

According to the conventional technology, after performing a certain amount of processes, the maintenance is performed by wiping the chamber window with an abrasive or replacing the chamber window itself, and then, the deposition process is performed again. This results in a very large time loss for the entire process, and a very large economic loss due to the cost of replacing the chamber window.

Patent Document 1 discloses a configuration that protects a laser window based on a screen, but since the number of screens is structurally limited, it is suitable for experimental purposes, etc., but has a limitation in that the chamber window protection efficiency is lower than that of existing efficiency for production purposes.

### PRIOR ART DOCUMENTS

### Patent Documents

### (Patent Document 1) KR10-0745610B

### (Patent Document 2) KR10-2275410B

### SUMMARY

The present disclosure provides a device for preventing contamination of a chamber window in pulsed laser deposition, which enables a deposition process to be performed for a long time by protecting the chamber window based on a predetermined film, thereby preventing the deposition material from being deposited on the chamber window.

In an embodiment, a device for preventing contamination of a chamber window in pulsed laser deposition, which is equipped in a pulsed laser deposition device may include: a film part disposed within a predetermined distance from the chamber window of a vacuum chamber; and a film transfer device configured to transfer the film part, wherein the contamination of the chamber window is prevented based on the film part, and the film part is transferred based on the film transfer device so that the pulsed laser is controlled to pass through an uncontaminated portion of the film part.

The film transfer device may include: a cover part attached to the inside of the vacuum chamber and disposed to cover the chamber window; an opening provided at one side of the cover part and disposed at a rear side of the chamber window based on an incident direction of the pulsed laser; an unwinding roller which is disposed at one side of the inside of the cover part and from which the film part is unwound; a winding roller which is disposed at the other side of the inside of the cover part and from which the film part unwound from the unwinding roller and passing through the opening is wound; and a first motor configured to rotate the unwinding roller and the winding roller.

The film part may be provided in a predetermined rectangular shape, and the film transfer device may include: a cover part attached to the inside of the vacuum chamber and disposed to cover the chamber window; an opening provided at a center of the cover part and disposed at a rear side of the chamber window based on an incident direction of the pulsed laser; a fixing jig configured to fix the film part; a first actuator configured to vertically transfer the fixing jig; and a second actuator configured to horizontally transfer the fixing jig, wherein the film part may be configured to alternately perform a first transfer process in which the film part is transferred in a horizontal direction by a first length, and a second transfer process in which the film part is transferred in a vertical direction by a second length.

The opening may include: a brush that is disposed at a predetermined distance from the vacuum chamber and is attached to one surface facing the chamber window, the fixing jig may include: an upper end bar to which an upper end of the film part is fixed; a left end bar which extends downward from a left end of the upper end bar and to which the left end of the film part is fixed; a right end bar which extends downward from a right end of the upper end bar and to which a right end of the film part is fixed; and a lower end bar which extends between the left and right end bars and to which a lower end of the film part is fixed, and the first actuator may include: a second motor disposed at one side of the inside of the cover part; a first screw shaft that is a rotational axis of the second motor; a first bearing configured to support an end of the first screw shaft; a first-1 guide connected to the first screw shaft; a first support disposed at the other side of the inside of the cover part; and a first-2 guide connected to the first support, the second actuator may include a third motor fixed to one side of the first-1 guide or the first-2 guide; a second screw shaft that is a rotation axis of the third motor; a second bearing fixed to one side of the first-2 guide or the first-1 guide; a second-1 guide connected to a second screw shaft; a second support fixed between the first-1 guide and the first-2 guide; and a second-2 guide connected to the second support, wherein one side of the upper end bar, the upper end of the left end bar, or the upper end of the right end bar may be fixed to the second-1 guide, and one side of the lower end bar, the lower end of the left end bar, or the lower end of the right end bar may be fixed to the second-2 guide.

The opening may include: a brush that is disposed at a predetermined distance from the vacuum chamber and is attached to one surface facing the chamber window, the fixing jig may include: an upper end bar to which an upper end of the film part is fixed; a left end bar which extends downward from a left end of the upper end bar and to which the left end of the film part is fixed; a right end bar which extends downward from a right end of the upper end bar and to which a right end of the film part is fixed; and a lower end bar which extends between the left and right end bars and to which a lower end of the film part is fixed, and the first actuator may include: a second motor disposed at one side of the inside of the cover part; a first screw shaft that is a rotational axis of the second motor; a first bearing configured to support an end of the first screw shaft; a first-1 guide connected to the first screw shaft; a first support disposed at the other side of the inside of the cover part; and a first-2 guide connected to the first support; and the second actuator may include: a third motor fixed to one side of the first-1 guide or the first-2 guide; a second screw shaft that is a rotation axis of the third motor; a second bearing fixed to one side of the first-2 guide or the first-1 guide; a second-1 guide connected to a second screw shaft; a second support fixed between the first-1 guide and the first-2 guide; and a second-2 guide connected to the second support, wherein one side of the upper end bar, the upper end of the left end bar, or the upper end of the right end bar may be fixed to the second-1 guide, and one side of the lower end bar, the lower end of the left end bar, or the lower end of the right end bar may be fixed to the second-2 guide.

The device may further include a film contamination detection device, wherein the film contamination detection device may include: a light emitting part that irradiates light from the outside of the chamber window to the chamber window at a predetermined angle; a light receiving part that is disposed at a point at which reflected light is received in response to an illumination incident angle of the light receiving part; and a detection control part that is connected to the light emitting part and the light receiving part to determine whether the film part is contaminated, the detection control part may be controlled according to a control method, which includes: starting visible light photography from the light receiving part; waiting for a first period; irradiating visible light having a first color from the light emitting part for a second period; irradiating visible light having a second color from the light emitting part for a third period; irradiating visible light having a third color from the light emitting part for a fourth period; irradiating infrared light from the light emitting part for a sixth period; starting ultraviolet photography from the light receiving part; waiting for a seventh period; irradiating ultraviolet light from the light emitting part for an eighth period; terminating the photography from the light receiving part; and determining whether the film part is contaminated based on an image photographed by the light receiving part in the first to eighth periods, wherein the determining of whether the film part is contaminated may include: extracting a color code corresponding to each pixel constituting a first frame from the first frame included in the first period in the image calculate a first matrix; extracting a color code corresponding to each pixel constituting a second frame from the second frame included in the second period in the image to calculate a second matrix; extracting a color code corresponding to each pixel constituting a third frame from the third frame included in the third period in the image to calculate a third matrix; extracting a color code corresponding to each pixel constituting a fourth frame from the fourth frame included in the fourth period in the image to calculate a fourth matrix; extracting a color code corresponding to each pixel constituting a fifth frame from the fifth frame included in the fifth period in the image to calculate a fifth matrix; extracting a color code corresponding to each pixel constituting a sixth frame from the sixth frame included in the sixth period in the image to calculate a sixth matrix; extracting a color code corresponding to each pixel constituting a seventh frame from the seventh frame included in a seventh period in the image to calculate a seventh matrix; extracting a color code corresponding to each pixel constituting an eighth frame from the eighth frame included in an eighth period in the image to calculate an eighth matrix, calculating ‘first matrix−second matrix=ninth−1 matrix’, ‘first matrix−third matrix=ninth−2 matrix’, ‘first matrix−fourth matrix=ninth−3 matrix’, ‘fifth matrix−sixth matrix=ninth−4 matrix’, and ‘seventh matrix−eighth matrix=ninth−5 matrix’, calculating a matrix formula for each of the ninth-1 to ninth-5 matrices; and determining that the film part 1 is contaminated when at least one of the matrix formula is equal to or greater than a threshold value.

### BRIEF DESCRIPTION OF THE DRAWINGS

Exemplary embodiments can be understood in more detail from the following description taken in conjunction with the accompanying drawings, in which:

FIG. 1 a flowchart illustrating a deposition process in a pulsed laser deposition apparatus;

FIG. 2 is a view illustrating the pulsed laser deposition apparatus;

FIGS. 3A-3B are views illustrating a device for preventing a chamber window from being contaminated in pulsed laser deposition according to an embodiment of the present invention;

FIGS. 4A-4C are views illustrating a device for preventing a chamber window from being contaminated in pulsed laser deposition according to another embodiment of the present invention;

FIG. 5 is a view illustrating a unwinding roller structure of the device for preventing the chamber window from being contaminated in the pulsed laser deposition according to an embodiment of the present invention;

FIG. 6 is a view illustrating an actuator structure of the device for preventing the contamination of the chamber window in the pulsed laser deposition according to an embodiment of the present invention; and

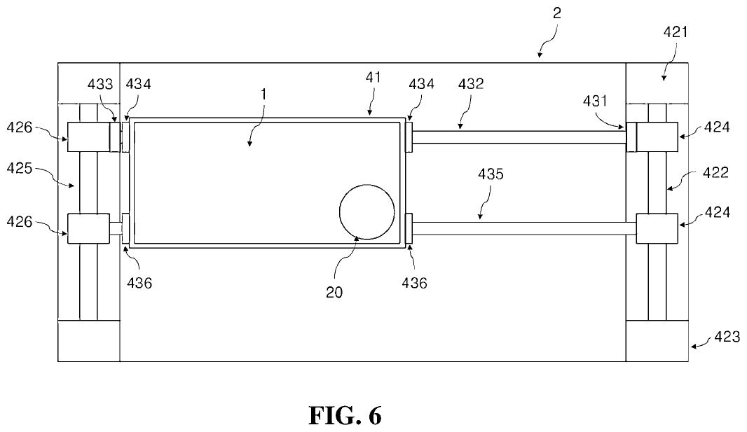

FIGS. 7A-7B are views illustrating a film part transfer method in the device for preventing the contamination of the chamber window in the pulsed laser deposition according to an embodiment of the present invention.

### DETAILED DESCRIPTION OF EMBODIMENTS

Hereinafter, embodiments will be described in detail with reference to the accompanying drawings. However, various changes may be made to the embodiments, so the scope of rights of the patent application is not restricted or limited by these embodiments. It should be understood that all changes, equivalents, or substitutes for the embodiments are included in the scope of rights.

Specific structural or functional descriptions of the embodiments are disclosed for illustrative purposes only and may be modified and implemented in various forms. Thus, the embodiments are not limited to the specific disclosed form, and the scope of the present specification includes changes, equivalents, or substitutes included in the technical spirit.

The terms such as first or second may be used to describe various components, but these terms should be interpreted only for the purpose of distinguishing one component from another component. For example, a first component may be named a second component, and similarly, a second component may also be named a first component.

It will also be understood that when an element is referred to as being ‘connected to’ another element, it can be directly connected to the other element, or intervening elements may also be present.

The terms used in the embodiments are for descriptive purposes only and should not be construed as limiting. The terms of a singular form may include plural forms unless referred to the contrary. In this specification, it should be understood that the terms such as “comprise/include” or “have” are intended to designate the presence of features, numbers, steps, operations, components, parts, or combinations thereof described in the specification, but does not exclude in advance the possibility of the existence or addition of elements, numbers, steps, operations, components, parts, or combinations thereof.

Unless otherwise defined, all terms used herein, including technical or scientific terms, have the same meaning as generally understood by a person of ordinary skill in the technical field to which the embodiments belong. Terms such as terms that are generally used and have been in dictionaries should be construed as having meanings matched with contextual meanings in the art. In this description, unless defined clearly, terms are not ideally, excessively construed as formal meanings.

In addition, when describing with reference to the accompanying drawings, identical components will be assigned the same reference numerals regardless of the reference numerals, and overlapping descriptions thereof will be omitted. In describing the embodiments, if it is determined that detailed descriptions related to known technologies may unnecessarily obscure the gist of the embodiments, the detailed descriptions are omitted.

Advantages and features of the present disclosure, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

In the embodiments of the present invention, unless otherwise defined, all terms used herein, including technical or scientific terms, are the same as those commonly understood by a person of ordinary skill in the technical field to which the present invention pertains. Terms defined in commonly used dictionaries should be interpreted as having meanings consistent with the meanings they have in the context of the relevant technology. In this description, unless defined clearly, terms are not ideally, excessively construed as formal meanings.

Since a shape, a ratio, an angle, a number, etc., which are shown in the accompanying drawings are exemplarily illustrated, the present disclosure is not limited thereto. Moreover, detailed descriptions related to well-known functions or configurations will be ruled out in order not to unnecessarily obscure subject matters of the present disclosure. When ‘comprising’, ‘having’, ‘consisting of ’, etc. are used, other components can be added unless ‘only’ is used. Even when a component is explained in singular number they may be interpreted as plural number.

In interpretation of the components, even though separate explicit expressions are not provided, they are to be interpreted as including general tolerance.

When positional relation of two portions is explained by ‘on’, ‘upper’, ‘lower’, ‘beside’, etc., one or more components may be positioned between two portions unless ‘just’ is not used. When portions are connected by ‘or’, the portions are interpreted as including ‘alone’ as well as ‘combination thereof’ but when portions are connected by ‘or’, ‘one of’, portions are interpreted as ‘alone’.

The size and thickness of each component shown in the drawings are shown for convenience of explanation, and the present invention is not necessarily limited to the size and thickness of the components shown.

Each feature of the various embodiments of the present invention can be partially or fully coupled or combined with each other, and as can be fully understood by those skilled in the art, various technical interconnections and operations are possible. Also, the embodiments may be independently performed with respect to each other or performed in combination of each other.

A superconductor is a material that has zero electrical resistance below a critical temperature (Tc) and exhibits perfect diamagnetism, which is called an Meissner effect. First-generation superconductivity was discovered first in 1911 when electrical resistance of mercury becomes zero a temperature of about 4.2 K in liquid helium, and second-generation superconductivity was discovered in 1986 when copper oxide superconductors were discovered.

It includes rare earth oxides represented by oxide superconductors (REBCO: RE is one or

more rare earth elements (Sc, Y, La, Ce, Pr, Nd, Pm, Sm, Eu, Gd, Tb, Dy, Ho, Er, Tm, Yb, and Lu)), and as oxides, (YBₐ₂Cu₃O₇₋ₓ), (GdBₐ₂Cu₃O₇₋ₓ) or, RE, Ba, Cu mean individual oxide particle substances, or two or more mean complex oxide particles among these elements.

The most important condition for using second-generation high-temperature superconductor (HTS) wires in superconducting applications is a high critical current (IC) value under high magnetic fields. In particular, the critical current density (JC) should be as large as possible even under large magnetic fields applied in an arbitrary direction. A limit of a critical current density is determined by an action of an artificial pin (flux pinning center) that prevents magnetic flux lines distributed inside the superconductor from moving against the Lorenz force when being invade from the outside to try to move due to the Lorenz force. Here, many researchers and inventors have developed a method to increase in critical current size under the magnetic fields by doping nano-sized non-superconducting particles into the superconducting layer.

In general, materials that constitute the artificial pins include at least one of BaHfO₃, SrHfO₃, CaHfO₃, BaZrO₃, BaSnO₃, etc., a solid solution thereof, or a mixture of two or more thereof.

The superconducting layer of REBCO-based high-temperature superconducting wires may be formed by various methods including pulsed laser deposition (PLD), metal organic chemical vapor deposition (MOCVD), metal organic deposition (MOD), and reactive co-evaporation (RCE).

Among them, the PLD method is particularly effective in obtaining two-axis oriented thin films. The PLD method that is one of the methods for depositing superconductors is known as the most convenient and effective technique for manufacturing high-temperature superconductors (HTS). In the deposition of the oxide superconducting layer using the PLD method, it is possible to form an oxide superconducting layer having good film quality and obtain high superconducting characteristics.

The PLD method is a method of striking a solid REBCO target using laser focused from a lens and separating the target material from a surface to form plasma in the form of a gas stream (plume), thereby crystallizing the plume material on the surface of a wire heated to a high temperature. The advantages of the PLD are that the thin film is formed with a chemical composition close to that of the target material, has low contamination, and has a high deposition rate. On the other hand, it has a disadvantage of low productivity compared to other manufacturing methods.

In order to increase in productivity in the PLD method, a method of increasing in deposition amount by irradiating the target with multiple lasers was being developed.

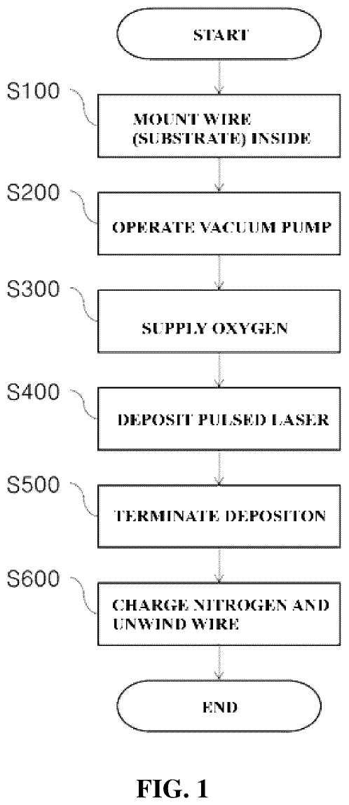

The pulsed laser deposition process may be performed according to the flowchart illustrated in FIG. 1.

The pulsed laser deposition device is equipped with an unwinding reel and a winding reel as units for transferring the substrate (wire). The reels may be configured as a separate chamber outside the chamber, and the wire may be fed by actuating the reel with a driving device. In order to transfer long wires, speeds of the unwinding reel and the winding reel have to be synchronized.

A vacuum chamber C is connected to a vacuum pump V so that a pressure inside the vacuum chamber C is reduced to a pressure that is suitable for process conditions.

A substrate heating unit heats a rear surface of the wire on which the deposition is being performed (electrical heater) to allow the deposition material to be deposited well during the deposition.

A target configured to have a cylinder shape (same composition as the material of the superconducting layer) may rotate around a center of the cylinder, and when the rotation is complete, the target may move horizontally to a left (right) side and then rotates again so that the target material is uniformly deposited on the outside of the cylinder to significantly improve productivity and uniformity/quality of the wire.

The pulsed laser may have a high energy density and thus be good to have a high output so as to obtain a vaporization amount of target.

Applicable laser types may include Ar-F (193 nm), Kr-F (248 nm), Xe-Cl (308 nm), excimer laser, YAG laser, and CO₂ laser.

An externally oscillated laser is introduced into the vacuum chamber C through a chamber window O provided on one surface of the vacuum chamber C. The chamber window O is treated with anti-reflective coating to prevent a laser beam L from being reflected.

After the inside of the vacuum chamber C is depressurized (vacuumed) using the vacuum pump V, an ionized gas from an oxygen ionization device is injected into the inside of the vacuum chamber C. An oxygen atmosphere is formed while maintaining an internal pressure of the vacuum chamber C constantly by controlling a flow control valve.

The atmospheric pressure may be adjusted during the PLD deposition so that an inclination angle and a length of the artificial pin are changed. In addition, the inclination angle and the length of the artificial pin may be adjusted according to a pulsed laser frequency of the PLD device and the atmospheric pressure inside the chamber.

When the deposition is complete, a nitrogen gas valve may introduce a nitrogen gas (dry air) into the chamber to adjusts the nitrogen gas to the same pressure as the atmospheric pressure and then may open the vacuum chamber C to finally unload a wire W.

According to an embodiment, in a device for preventing contamination of a chamber window O in pulsed laser L deposition, which is equipped in a pulsed laser L deposition device, the device includes a film part 1 disposed within a predetermined distance from the chamber window O of the vacuum chamber C, and a film transfer device that transfers the film part. Here, contamination of the chamber window O may be prevented based on the film part 1, and the film part 1 may be transferred based on the film transfer device so that the pulsed laser L is controlled to pass through an uncontaminated portion of the film part 1.

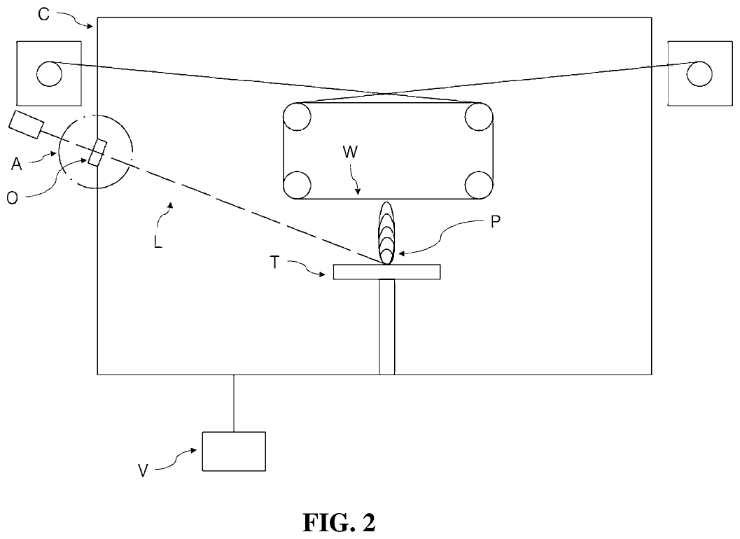

A configuration of a typical pulsed laser L deposition device used to manufacture superconducting wires, etc. is as shown in FIG. 2. When the pulsed laser L is irradiated onto a target T (thin film) through the chamber window O, the target T may be diffused in a state of a plume P and be deposited on the substrate W (deposition target) disposed thereon.

Here, since the deposition material diffused in the state of the plume P is not diffused only upward but also diffused radially, the deposition material may be deposited on the chamber window O and an inner circumferential surface of the vacuum chamber. Thus, transmittance of the pulsed laser L may be reduced, or some reflection/refraction may occur due to the material deposited on the chamber window O.

The contamination of the chamber window O may cause a thin film to be formed unevenly during the deposition process, thereby causing defects. To prevent this limitation, in the conventional technology, maintenance such as wiping the chamber window O or replacing the chamber window O may be performed every time, a certain amount of work may be performed.

In the technology described in prior art document 1, a pair of screens covering the chamber window O may be provided, and since the two screens intersect each other to protect the chamber window O, the deposition operation may be extended until the two screens become contaminated.

However, there was a limitation in that it is not possible to significantly increase in continuous process time because it was equipped with only two screens and structurally could only accommodate four screens.

In an embodiment of the present invention, the film part 1 may be unwound or moved vertically and horizontally, and only a portion of the film part 1 may be exposed so that the contamination of the chamber window O is prevented for a long time.

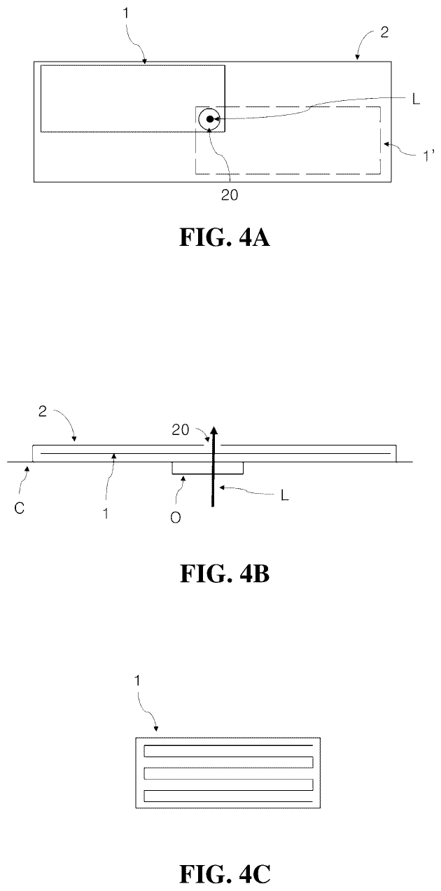

For example, in an embodiment according to the ‘rectangular (see FIGS. 4A-4C)’ film part 1 described below, if an area of an opening 20 is about 1, and an area of the film part 1 is about 30, the process may be continuously performed for up to about 30 times the existing process time.

The film part 1 and the chamber window O are treated with anti-reflection coating, and thus, most components of the pulsed laser L and the like may not be reflected and be transmitted to the target T.

In the above description, that ‘the pulsed laser L is controlled to pass through the uncontaminated portion of the film part 1’ refers to controlling the pulsed laser L to pass through a portion at which the contamination by the deposition material does not occur by exposing a portion of an area of the film part 1, which has not yet been exposed to the opening 20, to the opening 20.

For example, in the ‘rectangular’ film part 1, the deposition process may be performed for B hours by positioning an area A in the opening 20, and then, when it is determined that the area A is contaminated to a level higher than the standard, the film part 1 may move horizontally or vertically, and then, the deposition process may be performed again for D hours on an area C.

In addition, the film transfer device may include a cover part 2 attached to the inside of the vacuum chamber C and disposed to cover the chamber window O, an opening 20 provided at one side of the cover part 2 and disposed at a rear side of the chamber window O based on an incident direction of the pulsed laser L, an unwinding roller 31 which is disposed at one side of the inside of the cover part 2 and from which the film part 1 is unwound, a winding roller 32 which is disposed at the other side of the inside of the cover part 2 and from which the film part 1 unwound from the unwinding roller 31 and passing through the opening 20 is wound, and a first motor that rotates the unwinding roller 31 and the winding roller 32.

The foregoing embodiment is an embodiment of a method in which the film part 1 having a predetermined length is wound around the unwinding roller 31 and installed inside the vacuum chamber C, and when the process is in progress, the winding roller 32 or/and the unwinding roller 31 are rotated continuously or intermittently to expose a portion of the film part 1 that is not contaminated through the opening 20.

The cover part 2 may be fixed to the inside of the vacuum chamber C to cover the chamber window O, thereby preventing the deposition material from being in contact with the film part 1.

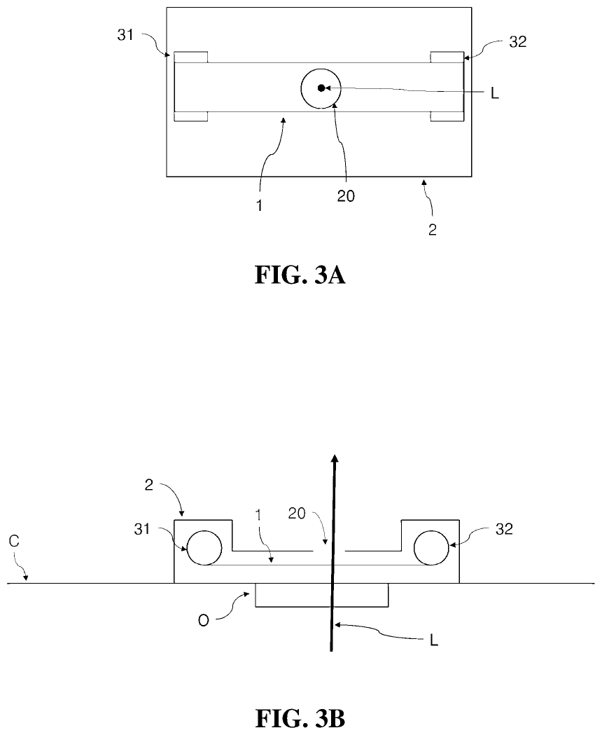

The opening 20 may be defined in a circular shape at one side of the cover part 2 as illustrated in FIGS. 3A-3B or 4.

FIG. 3(a) is a view when the cover part 2 is viewed from the inside of the vacuum chamber C, and FIG. 3(b) is a view when the cover part 2 is viewed from an upper portion of the vacuum chamber C.

For convenience of explanation, FIG. 3(a) illustrates the winding roller 32, the unwinding roller 31, and the film part 1 disposed inside the cover part 2, but in reality, these portions are covered by the cover part 2, and only a portion of the film part 1 is exposed inside the opening 20.

The film part 1 that has been exposed to the deposition material for a certain time through the opening 20 and is partially contaminated may be wound on the winding roller 32.

In addition, the film part 1 may be provided in a predetermined rectangular shape, and the film transfer device may include: a cover part 2 attached to the inside of the vacuum chamber C and disposed to cover the chamber window O, an opening 20 provided at a center of the cover part 2 and disposed at a rear side of the chamber window O based on an incident direction of the pulsed laser L, a fixing jig 41 configured to fix the film part 1, a first actuator configured to vertically transfer the fixing jig 41, and a second actuator configured to horizontally transfer the fixing jig 41. Thus, the film part 1 may be configured to alternately perform a first transfer process in which the film part 1 is transferred in a horizontal direction by a first length, and a second transfer process in which the film part 1 is transferred in a vertical direction by a second length.

The foregoing embodiment is an embodiment of a method in which the rectangular film part 1 is installed inside the vacuum chamber C, and, and while the process is in progress, the film part 1 continuously or intermittently moves vertically or horizontally to expose a portion of the film part 1 that is not contaminated through the opening 20.

The fixing jig 41 may fix the film part 1 to maintain predetermined tension on the film part 1. Thus, the film part 1 may be exposed to the opening 20 in a state of being tightly unfolded, and thus, the pulsed laser L may be transmitted without being refracted/reflected and be irradiated onto the target T.

First, the process may start in a state in which one corner of the film part 1 is exposed to the opening 20, and then, if the exposed portion is judged to be contaminated, the film part 1 may move to the left or right (first moving process) to expose the uncontaminated film part 1 and cover the contaminated film part 1 so that the uncontaminated film part 1 is accommodated inside the cover part 2. This process may be repeatedly performed, and then, after a first line of the film part 1 has been completely contaminated, the second transfer process may be performed to transfer the film part 1 upward or downward.

Thereafter, after the second line of the film part 1 is contaminated, the process may be performed by transferring the film part 1 again in the right or left direction (an opposite direction to the direction in which the film part 1 is previously transferred).

According to the above-described process, the film part 1 may be transferred along a trajectory of the shape illustrated in FIG. 4(c).

FIG. 4(a) illustrates a position of the film part 1 before the process starts and a position of a film part 1′ after the process is terminated.

In addition, the opening 20 may include: a brush that is disposed at a predetermined distance from the vacuum chamber C and is attached to one surface facing the chamber window O.

The brush may be applied to both the embodiments of a winding-type film part 1 and a rectangular film part 1.

The above-described unwinding roller 31 may include a first roller 311 installed inside the vacuum chamber C in a state in which the film part 1 is wound to a predetermined length, a second roller 312 disposed to be spaced a first length from the first roller 311 in a first direction, and a third roller 313 disposed to be spaced a second length from the second roller 312 in a ‘second direction having a predetermined acute angle with respect to the first direction’, and the third roller 313 may be disposed so that a virtual plane connecting a central axis of the third roller 313 to a central axis of the winding roller 32 is parallel to the chamber window O.

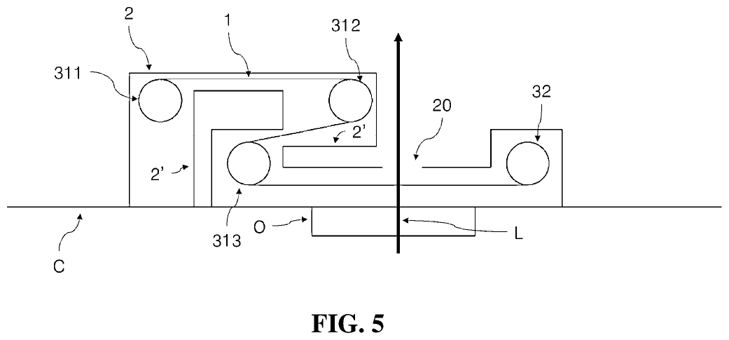

The unwinding roller 31 and the winding roller 32 may be disposed in a predetermined ‘Z’ shape (so that a line connecting a rotation axes of a first roller 311−second roller 312−third roller 313−winding roller 32 forms a ‘Z’ shape) as illustrated in FIG. 5, and thus, the film part 1 that is not exposed to the opening 20 may be prevented from being contaminated by the deposition material even when the deposition material passes through the brush or in an embodiment without the brush.

A cover part 2′ may protrude between the film parts 1 disposed in the ‘Z’ shape to block the plume flowing into the inside of the cover part 2 from approaching the first roller 311 or the second roller 312.

In addition, the fixing jig 41 may include an upper end bar to which an upper end of the film part 1 is fixed, a left end bar which extends downward from a left end of the upper end bar and to which the left end of the film part 1 is fixed, a right end bar which extends downward from a right end of the upper end bar and to which a right end of the film part 1 is fixed, and a lower end bar which extends between the left and right end bars and to which a lower end of the film part 1 is fixed. The first actuator may include a second motor 421 disposed at one side of the inside of the cover part 2, a first screw shaft 422 that is a rotational axis of the second motor 421, a first bearing 423 configured to support an end of the first screw shaft 422, a first-1 guide 424 connected to the first screw shaft 422, a first support 425 disposed at the other side of the inside of the cover part 2, and a first-2 guide 426 connected to the first support 425. The second actuator may include a third motor 431 fixed to one side of the first-1 guide 424 or the first-2 guide 426, a second screw shaft 432 that is a rotation axis of the third motor 431, a second bearing 433 fixed to one side of the first-2 guide 426 or the first-1 guide 424, a second-1 guide 434 connected to a second screw shaft 432, a second support 435 fixed between the first-1 guide 424 and the first-2 guide 426, and a second-2 guide 436 connected to the second support 435. One side of the upper end bar, the upper end of the left end bar, or the upper end of the right end bar may be fixed to the second-1 guide 434, and one side of the lower end bar, the lower end of the left end bar, or the lower end of the right end bar may be fixed to the second-2 guide 436.

The fixing jig 41 may be provided to fix four edge of the film part 1 so that predetermined tension is maintained on the film part 1 and may be connected to the first actuator and the second actuator so that a point exposed to the opening 20 is changed.

The first actuator may move the second actuator in the upward and downward direction (vertical direction) based on a ball screw structure.

The second motor 421 may be installed inside the vacuum chamber C and receives current to rotate, thereby rotating the first screw shaft 422.

When the first screw shaft 422 rotates, the first-1 guide 424 connected to the first screw shaft 422 may move vertically along a screw thread, and the first-2 guide 426 fixed/connected to the first-1 guide 424 by the fixing jig 41 may move vertically along the first support 425.

The second actuator may move the fixing jig 41/film part 1 in the left and right direction (horizontal direction) based on the ball screw structure.

The second actuator of which a vertical position is determined by the first actuator may adjust a position of the second-1 guide 434 in the left and right direction based on the third motor 431, thereby adjusting the point at which the film part 1 is exposed to the opening 20.

The film transfer device may be controlled to transfer the film part continuously at a predetermined constant speed or to transfer the film part at a predetermined time interval.

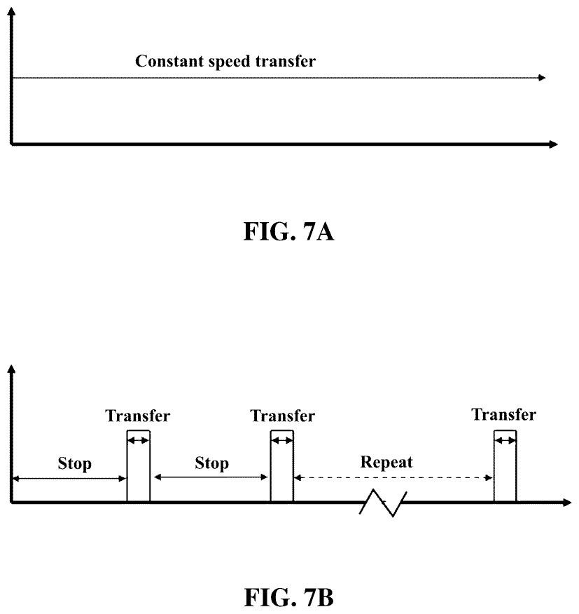

FIGS. 7A-7B are views illustrating a transfer speed of the film part 1. FIG. 7(a) illustrates an example of continuously transferring the film part 1 at a constant speed during the process, and FIG. 7(b) illustrates an example of transferring the film part 1 at a constant speed when the contamination of the film part 1 is detected/judged or at a regular time interval.

When the film part 1 is transferred as in FIG. 7(a), a decrease in film uniformity due to the contaminated film part 1 hardly occurs, and thus, quality of a product may be maintained very high, and when the film part 1 is transferred as in FIG. 7(b), consumption of the film part 1 may be minimized, and thus, costs of replacing the film part 1 and a maintenance time may be reduced.

In addition, a film contamination detection device may be further provided. The film contamination detection device may include a light emitting part that irradiates light from the outside of the chamber window O to the chamber window O at a predetermined angle, a light receiving part that is disposed at a point at which reflected light is received in response to an illumination incident angle of the light receiving part, and a detection control part that is connected to the light emitting part and the light receiving part to determine whether the film part 1 is contaminated. The detection control part may be controlled according to a control method, which includes starting visible light photography from the light receiving part, waiting for a first period, irradiating visible light having a first color from the light emitting part for a second period, irradiating visible light having a second color from the light emitting part for a third period, irradiating visible light having a third color from the light emitting part for a fourth period, irradiating infrared light from the light emitting part for a sixth period, starting ultraviolet photography from the light receiving part, waiting for a seventh period, irradiating ultraviolet light from the light emitting part for an eighth period, terminating the photography from the light receiving part, and determining whether the film part 1 is contaminated based on an image photographed by the light receiving part in the first to eighth periods. The determining of whether the film part 1 is contaminated may include extracting a color code corresponding to each pixel constituting a first frame from the first frame included in the first period in the image calculate a first matrix, extracting a color code corresponding to each pixel constituting a second frame from the second frame included in the second period in the image to calculate a second matrix, extracting a color code corresponding to each pixel constituting a third frame from the third frame included in the third period in the image to calculate a third matrix, extracting a color code corresponding to each pixel constituting a fourth frame from the fourth frame included in the fourth period in the image to calculate a fourth matrix, extracting a color code corresponding to each pixel constituting a fifth frame from the fifth frame included in the fifth period in the image to calculate a fifth matrix, extracting a color code corresponding to each pixel constituting a sixth frame from the sixth frame included in the sixth period in the image to calculate a sixth matrix, extracting a color code corresponding to each pixel constituting a seventh frame from the seventh frame included in a seventh period in the image to calculate a seventh matrix, extracting a color code corresponding to each pixel constituting an eighth frame from the eighth frame included in an eighth period in the image to calculate an eighth matrix, calculating ‘first matrix-second matrix =ninth-1 matrix’, ‘first matrix−third matrix=ninth−2 matrix’, ‘first matrix−fourth matrix=ninth−3 matrix’, ‘fifth matrix−sixth matrix=ninth−4 matrix’, and ‘seventh matrix−eighth matrix=ninth−5 matrix’, calculating a matrix formula for each of the ninth-1 to ninth-5 matrices, and determining that the film part 1 is contaminated when at least one of the matrix formula is equal to or greater than a threshold value.

The light emitting part may be configured in the form of a module/system capable of irradiating the visible light, the infrared rays, and the ultraviolet rays having a plurality of different colors.

The light receiving part may be a predetermined camera module/system that is capable of photographing and detecting the visible light, the infrared rays, and the ultraviolet rays irradiated by the light emitting part.

In the starting of the visible light photography from the light receiving part, an operation of the pulsed laser L may be temporarily stopped, and it may be detected (photographed) whether the light irradiated from the light receiving part is refracted/reflected by the chamber window O and the film part 1 and is introduced the light receiving part (continuous photography during the first to fourth periods).

In the waiting for the first period, the visible light photography may be continued to secure a sufficient number of frames of the image while the light emitting part is not operating.

In the irradiating of the visible light having the first color from the light emitting part for the second period, the irradiating of the visible light having the second color from the light emitting part for the third period, and the irradiating of the visible light having the third color from the light emitting part for the fourth period, it is photographed whether the visible light having three different colors is refracted/reflected by the chamber window O/film part 1 in the image.

Thereafter, the contamination of the film part 1 may be detected/judged by comparing the image frames in the first period in which the light emitting part does not operate with the image frames in the second to fourth periods according to the processes described below.

In the starting of the infrared photography from the light receiving part, the irradiation of the visible light from the light emitting part may be stopped, and the photograph with the infrared camera may begin.

In the waiting for the fifth period, the image may be photographed in a state in which the infrared rays are not irradiated from the light emitting part.

In the irradiating of the infrared rays from the light emitting part for the sixth period, the image may be photographed by the infrared camera of the light receiving part during the sixth period in which the light emitting part irradiates the infrared rays.

In the starting of the ultraviolet photography from the light receiving part, the infrared irradiation from the light emitting part may be stopped, and the photography with the ultraviolet camera may begin.

In the waiting for the seventh period, the image may be photographed in a state in which the ultraviolet rays are not irradiated from the light emitting part.

In the irradiating of the ultraviolet rays from the light emitting part for the eighth period, the image may be photographed by the infrared camera of the light receiving part during the eighth period in which the light emitting part irradiates the ultraviolet rays.

In the terminating of the photography of the light receiving part, the photography from all the cameras of the light receiving part may be stopped after the first to eighth periods.

In the determining of whether the film part 1 is contaminated based on the images photographed by the light receiving part during the first to eighth periods, the visible light images, the infrared images, and the ultraviolet images photographed in the state in which the visible light, the infrared and the ultraviolet light are not irradiated, and the visible light images, the infrared images, and the ultraviolet images photographed in the state in which the visible light, the infrared and the ultraviolet light are irradiated are compared to determine whether the film part 1 is contaminated.

In the extracting of the color code corresponding to each pixel constituting the first frame from the first frame included in the first period in the image to calculate the first matrix, the first frame, which is one frame of the image corresponding to the first period, may be extracted, and the color code (#000000 to #FFFFFF) for each pixel may be extracted from the first frame to calculate the first matrix having each color code for each pixel as a component.

Here, the image may be provided as a predetermined square image (the number of horizontal and vertical pixels is the same), and the first matrix generated accordingly may become a square matrix.

The calculating of the second matrix and the calculating of the eighth matrix may be performed/processed in the same manner as described above.

In the calculating of ‘first matrix−second matrix=ninth−1 matrix’, ‘first matrix−third matrix=ninth−2 matrix’, ‘first matrix−fourth matrix=ninth−3 matrix’, ‘fifth matrix−sixth matrix=ninth−4 matrix’, and ‘seventh matrix−eighth matrix=ninth−5 matrix’, a difference operation may be performed based on the total of eight calculated matrices, and thus, the ninth-1 to ninth-5 matrices may be calculated.

The matrices produced by the difference operation may data that represents a difference before and after the operation of the light emitting part.

In the calculating of the determinant for each of the ninth-1 to ninth-5 matrices, the determinant for each of the ninth-1 to ninth-5 matrices, which are square matrices, may be calculated, and based on this, it may be possible to determine how much of three different colors of the visible light, the infrared rays, and the ultraviolet rays are reflected and received by the light receiving part.

In the determining of whether the film part 1 is contaminated when at least one of the above matrix formula is greater than or equal to the threshold value, the film part 1 may be determined to be contaminated when the calculated determinant is greater than or equal to a predetermined threshold value.

Here, the threshold value may be specified differently for each determinant of the ninth-1 to ninth-5 matrices.

For example, when the threshold for the determinant of the ninth-1 matrix is about 35, the threshold for the determinant of the ninth-5 matrix may be specified as about 24.

According to the embodiments, the chamber window provided in the vacuum chamber may be prevented from being contaminated by the deposition material in the pulsed laser deposition process, and thus, the deposition process may be performed continuously for a long time.

In addition, the anti-reflective coated film may be transferred into the vacuum chamber so that the different portions of the thin film are positioned to cover the chamber window over time to maximizing the replacement cycle of the film.

In addition, the predetermined brush may be disposed around the periphery of the

opening through which the film is exposed, thereby preventing the films, which are not yet expose to the opening, from being contaminated.

In addition, the device may be designed based on the windable film or a predetermined rectangular film to design a contamination prevention device according to the film material or other process environment.

In addition, the unwinding roller may be disposed in the zigzag (Z shape) to prevent the film wound on the unwinding roller from being contaminated.

In addition, the rectangular film may be transferred in two-axis directions based on the two actuators.

In addition, the contamination of the film may be detected to appropriately adjust the transfer cycle of the film.

Although embodiments of the present invention have been described in more detail with reference to the accompanying drawings, the present invention is not necessarily limited to these embodiments, and various modifications may be made without departing from the technical spirit of the present invention. Thus, the embodiment of the present invention is to be considered illustrative, and not restrictive, and the technical spirit of the present invention is not limited to the foregoing embodiment. Therefore, the embodiments described above should be understood in all respects as illustrative and not restrictive. Therefore, the scope of the present disclosure is defined not by the detailed description of the invention but by the appended claims, and all differences within the scope will be construed as being included in the present disclosure.

Therefore, other implementations, other embodiments, and equivalents of the claims also fall within the scope of the following claims.

What is claimed is:

1. A device for preventing contamination of a chamber window in pulsed laser deposition, which is equipped in a pulsed laser deposition device, the device comprising:
a film part disposed within a predetermined distance from the chamber window of a vacuum chamber; and
a film transfer device configured to transfer the film part,
wherein the contamination of the chamber window is prevented based on the film part, and
the film part is transferred based on the film transfer device so that the pulsed laser is controlled to pass through an uncontaminated portion of the film part.

2. The device of claim 1, wherein the film transfer device comprises:
a cover part attached to the inside of the vacuum chamber and disposed to cover the chamber window;
an opening provided at one side of the cover part and disposed at a rear side of the chamber window based on an incident direction of the pulsed laser;
an unwinding roller which is disposed at one side of the inside of the cover part and from which the film part is unwound;
a winding roller which is disposed at the other side of the inside of the cover part and from which the film part unwound from the unwinding roller and passing through the opening is wound; and
a first motor configured to rotate the unwinding roller and the winding roller.

3. The device of claim 1, wherein the film part is provided in a predetermined rectangular shape, and
the film transfer device comprises:
a cover part attached to the inside of the vacuum chamber and disposed to cover the chamber window;
an opening provided at a center of the cover part and disposed at a rear side of the chamber window based on an incident direction of the pulsed laser;
a fixing jig configured to fix the film part;
a first actuator configured to vertically transfer the fixing jig; and
a second actuator configured to horizontally transfer the fixing jig,
wherein the film part is configured to alternately perform a first transfer process in which the film part is transferred in a horizontal direction by a first length, and a second transfer process in which the film part is transferred in a vertical direction by a second length.

4. The device of claim 1, wherein the film transfer device is controlled to transfer the film part continuously at a predetermined constant speed or to transfer the film part at a predetermined time interval.

5. The device of claim 1, further comprising a film contamination detection device, wherein the film contamination detection device comprises:
a light emitting part that irradiates light from the outside of the chamber window to the chamber window at a predetermined angle;
a light receiving part that is disposed at a point at which reflected light is received in response to an illumination incident angle of the light receiving part; and
a detection control part that is connected to the light emitting part and the light receiving part to determine whether the film part is contaminated.
